(19) United States
(12) Patent Application Publication
(10) Pub. No.: US 2009/0189625 A1
(43) Pub. Date: Jul. 30, 2009

(54) Method and System for Continuity Testing of Conductive Interconnects

(75) Inventor: Larry G. Taunton, McKinney, TX (US)

Correspondence Address: BAKER BOTTS LLP, 2001 ROSS AVENUE, 6TH FLOOR, DALLAS, TX, 75201-2980, US

(73) Assignee: Raytheon Company, Waltham, MA (US)

(21) Appl. No.: 12/357,934

(22) Filed: Jan. 22, 2009

Related U.S. Application Data
(60) Provisional application No. 61/023,733, filed on Jan. 25, 2008.

(51) Int. Cl. G01R 31/02

(52) U.S. Cl. 324/754

(57) ABSTRACT

In accordance with one embodiment of the present disclosure, a method for testing electronics includes forming at least a portion of an electrical circuit by electrically coupling a plurality of indicators in series with respect to each other such that each indicator is operable to substantially simultaneously indicate an electrical characteristic of a respective one or more of a plurality of conductive interconnects. Respective ones of the plurality of conductive interconnects are coupled to a respective pair of a plurality of reception nodes of the electrical circuit such that each conductive interconnect is coupled to the electrical circuit in parallel with a respective one of a plurality of indicators. The method also includes determining, based at least in part on the electrical characteristics indicated by at least three of the plurality of indicators, whether two of the plurality of conductive interconnects are electrically shorted together.

### RELATED APPLICATION

This application claims benefit under 35 U.S.C. § 119(e) of U.S. Provisional Application Ser. No. 61/023,733, entitled “METHOD AND SYSTEM FOR CONTINUITY TESTING OF CONDUCTIVE INTERCONNECTS” filed Jan. 25, 2008, by Larry G. Taunton.

### TECHNICAL FIELD

This disclosure relates in general to electronics testing, and more particularly to a method and system for continuity testing of conductive interconnects.

### BACKGROUND

Electrical devices and systems typically include some form of electrical interconnections. Electrical interconnections may include multiple wires assembled into cables or multiple electrical traces printed on a board, for example. Error in the fabrication of electrical interconnections may result in short circuits, open circuits, and/or intermittent connections, all of which might, in some instances, risk catastrophic failure and potentially human injury.

### SUMMARY

In accordance with one embodiment of the present disclosure, a method for testing electronics includes forming at least a portion of an electrical circuit by electrically coupling a plurality of indicators in series with respect to each other such that each indicator is operable to substantially simultaneously indicate an electrical characteristic of a respective one or more of a plurality of conductive interconnects. Respective ones of the plurality of conductive interconnects are coupled to a respective pair of a plurality of reception nodes of the electrical circuit such that each conductive interconnect is coupled to the electrical circuit in parallel with a respective one of a plurality of indicators. The method also includes determining, based at least in part on the electrical characteristics indicated by at least three of the plurality of indicators, whether two of the plurality of conductive interconnects are electrically shorted together.

Certain embodiments of the present disclosure provide a continuity testing device that inherently confirms whether or not it is functioning properly. Some embodiments may perform continuity testing efficiently by inserting a test cable into mating connectors of the continuity testing device, without any further switching. Various embodiments may provide discrete indications that specifically identify which particular interconnect(s) have a problem when multiple interconnects are simultaneously tested. Some embodiments may be highly economical, easily reproducible, and even expendable.

Other technical advantages of the present disclosure will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present disclosure and its advantages, reference is now made to the following description, taken in conjunction with the accompanying drawings, in which:

FIG. 1A is a schematic for an example circuit that may form a portion of a continuity testing device according to one embodiment;

FIG. 1B is an example continuity testing device that may house the circuit of FIG. 1A according to one embodiment;

FIG. 2 is a table indicating example observations that may be made regarding the testing of conductive interconnects using the circuit of FIG. 1A housed within the continuity testing device of FIG. 1B according to one embodiment; and

FIG. 3 is a schematic for a circuit that may be used to expand the testing capability of the circuit of FIG. 1A.

### DETAILED DESCRIPTION

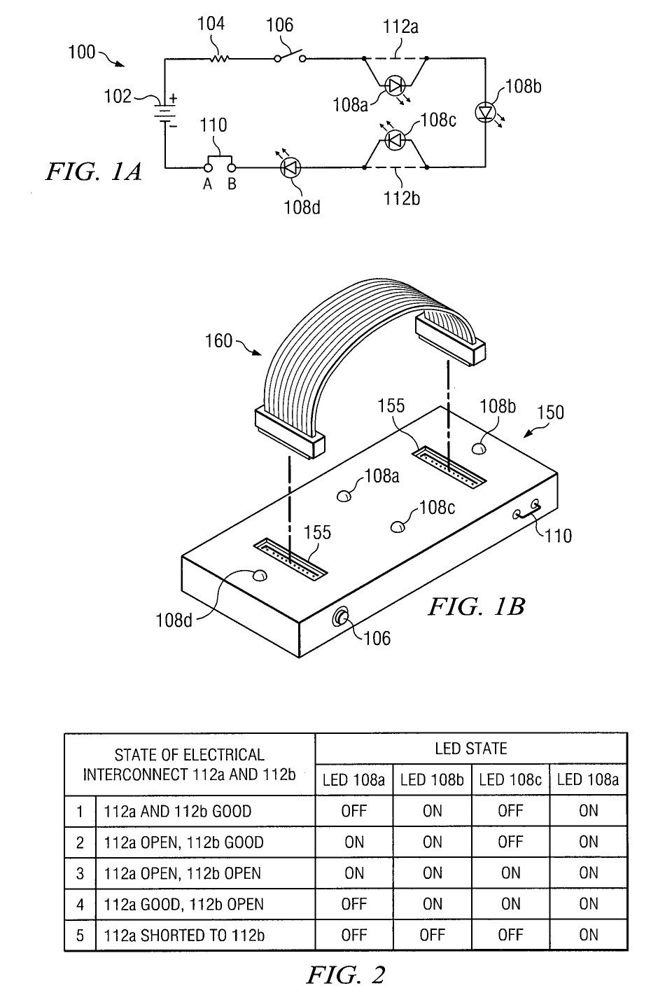

The various embodiments disclosed herein may be used in any of a variety of applications including, for example, portable, cost-effective, self-diagnosing, electronic testing devices configured to simultaneously test multiple interconnects for respective short circuits, open circuits, and/or intermittent connections. Particular examples specified throughout this document are intended for example purposes only, and are not intended to limit the scope of the present disclosure. In particular, this document is not intended to be limited to a continuity testing device for flexible cabling. The example embodiments of the present disclosure are best understood by referring to FIGS. 1A to 2 of the drawings, like numerals being used for like and corresponding parts of the various drawings.

FIG. 1A is a schematic for a circuit 100 that may form a portion of a continuity testing device according to one embodiment. In this example, circuit 100 generally includes a voltage source 102, a resistor 104, a switch 106, multiple indicators 108a, 108b, 108c, and 108d, and a jumper 110, all connected in series with respect to each other. In operation, circuit 100 is generally configured to test the performance of multiple conductive interconnects 112a and 112b, which may be electrically coupled to circuit 100 in parallel with respect to respective indicator 108a and 108b. One example of a continuity testing device that may house circuit 100 is illustrated in FIG. 1B.

As shown in FIG. 1B, a continuity testing device 150 includes the components 102, 104, 106, 108, 110 of circuit 100 coupled to or within a portable chassis. In this example, continuity device 150 includes a pair of receptors 155 that are configured to couple with the ends of a cable 160 containing conductive interconnects 112. In some alternative embodiments, conductive interconnects 112 may connect to the continuity testing device 150 by means of a clip, binding post, an electrical connector, or by some other suitable approach. In some of the embodiments described below, after conductive interconnects 112 are installed certain LEDs 108 may illuminate to indicate whether the conductive interconnects 112 are functioning properly.

Referring now to FIG. 1A, voltage source 102 generally refers to any component(s) operable to provide a voltage to tester 100. In this example, voltage source 102 includes four nine-volt batteries, (e.g., Duracell MN-1604 batteries or their equivalent), yielding a potential of about 36 volts; however, any suitable component(s) operable to provide any suitable potential may be used. In some alternative embodiments, for example, voltage source 102 may be replaced by a power supply operating on alternating current (AC).

Resistor 104 generally refers to any component(s) operable to limit current to circuit 100. In this example, resistor 104 is selected according to Ohm's law to limit the current provided to each indicator 108 to a maximum of approximately 20 milliamps independent of the functionality of interconnects 112; however, circuit 100 may be designed to operate at any suitable current depending, for example, on the various specifications of indicators 108. Assuming the use of a 20 milliamps forward current and assuming a 2.0 volt nominal forward voltage drop, Vf, for each indicator 108, the resistance of resistor 104 is calculated by first adding the number of potential indicators 108 in series, which is four in this example. There is then a total forward voltage drop of 2.0 volts times 4 indicators 108, or 8 volts. For the net voltage source 102 potential of 36 volts, the resistor suitable for a 20 milliamps maximum may be calculated as 36 volts minus 8 volts, which equals 28 volts, divided by 0.020 amperes, or 1,400 ohms.

Switch 106 generally refers to any component operable to control current flow of circuit 100. In this example, switch 106 is a momentary-contact type; however, any suitable component operable to control current flow of circuit 100 may be used. In alternative embodiments operating from an AC-powered power, for example, the continuity testing device 150 may be left on at all times with very small power consumption. In general, low voltage potentials may be used, thus making the continuity testing device 150 of various embodiments safe for handling.

Each indicator 108 generally refers to any device capable of indicating an electrical characteristic of the conductive interconnects 112 under test and/or a diagnosis of circuit 100. In this example, indicators 108 are all semiconductor light emitting diodes (LEDs) that emit incoherent narrow-spectrum light when electrically biased in the forward direction; however, any suitable device may be used to indicate an electrical characteristic of the conductive interconnects 112 under test and/or a diagnosis of circuit 100, including, for example, a liquid crystal panel, a piezoelectric speaker, etc. In some embodiments, LEDs 108 using more or less current for their nominal ratings may be used and the current limiting resistance of resistor 104 may be selected accordingly. In this example, the color of LEDs 108 are selected to permit enhanced and easy recognition of the status (e.g., “go” or “no-go”) of the conductive interconnects 112 and the status of the continuity testing device 150 itself, as explained further below.

In this example, a removable jumper 110 bridges probe connection points A and B. Jumper 110 may be a short length of conductor used to close a break in, or bypass a part of, circuit 100. In some embodiments, connection points A and B permit the continuity testing device 150 to be used for simple continuity testing on a variety of wires and other conductors. After removing the jumper 110 connecting the probe connection points A and B, ordinary test probes may be connected to use the continuity testing device 150 for common continuity testing when switch 106 is in the “on” position, whether or not an electrical interconnect 112 is installed. For convenience, standard jacks may be used at connection points A and B.

Each electrical interconnect 112 generally refers to any conductive material configured so as to provide a conductive path between at least two points. For example, conductive interconnects 112a and 112b may be two or more conductive wires housed within a cable and operable to transmit supply and return connections of signals, and/or power. Some particular examples of conductive interconnects 112 include a coaxial cable, a wiring harness, conductive traces on a printed circuit board, printed circuit flexible cable, computer and telecom wiring, automobile wiring, aircraft wiring, audio/visual electronics wiring, etc. Although the illustrated embodiment includes only two conductive interconnects 112a and 112b, the testing of additional conductive interconnects 112 may be implemented, for example, by using a voltage source 102 operable to generate a greater voltage and a larger series resistor 104.

In operation, conductive interconnects 112 are coupled to circuit 100. In some cases conductive interconnects 112 may be directly coupled, as shown in FIG. 1B, or may be coupled by connecting wires, probes, etc. Some tests may involve connecting respective portions of one or more conductive interconnects 112, as opposed to testing the entire electrical interconnect(s) 112 by coupling its endpoints.

In some embodiments, “go” and “no-go” status indications of indicators 108 may be used to (i) confirm that the continuity testing device 150 is functioning properly, and (ii) to identify which of the coupled electrical interconnect(s) 112 have a problem, the nature of that problem, and whether multiple problems are interrelated, as described further with respect to FIG. 2. For enhanced and easy recognition of a “go” and “no-go” status, red LEDs may be used for indicators 108a and 108c, and green LEDs may be used for indicators 108b and 108d. In this manner, green is associated with a “go” status, indicating properly functionality, and red is associated with a “no-go” status, indicating a problem.

FIG. 2 is an example table 200 indicating observations that may be made regarding the testing of conductive interconnects using circuit 100 of FIG. 1A housed within the continuity testing device 150 of FIG. 1B according to one embodiment. Table 200 may be readily extended for any practical number of conductive interconnects 112 and for any of a variety of other observations or operational scenarios. In this example, each indicator 108 includes a respective LED 108. The proper operation of continuity testing device 150 is confirmed by the fact that LED 108d remains illuminated in all testing states, thus helping to assure that no ambiguous indication is observed; however, a non-illuminated LED 108d may indicate continuity testing device 150 is not functioning properly. Each row of FIG. 2 indicates the on or off state for each LED 108 (i.e. an illuminated or not illuminated state) of a respective operational scenario. As shown in FIG. 2, circuit 100 may be used to identify one or more problems associated with one or more particular conductive interconnects 112 while simultaneously testing multiple conductive interconnects. Although this example describes the on or off states of LEDs 108 for five different operational scenarios (i.e. five rows of table 200), the illustrated scenarios represent an example subset of all possible scenarios and any of a variety of other possible on or off states for LEDs 108 may be used to indicate other possible operational scenarios.

As shown in Row 1 of FIG. 2, the coupling of all or a portion of a properly functioning and/or properly wired electrical interconnect 112a in parallel with LED 108a shunts current around LED 108a, thereby causing LED 108a to not be illuminated. In like manner, the coupling of all or a portion of a properly functioning and/or properly wired electrical interconnect 112b in parallel with LED 108c shunts current around LED 108c, thereby causing LED 108c to not be illuminated. In this manner, a properly fabricated or “good” cable causes two diodes 108b and 108d to be illuminated for a V_{f} of 4.0 volts, resulting in a current of 36 volts minus 4 volts, which equals 32 volts, divided by 1,400 ohms, or 22.8 milliamps-a usable current with the two LEDs 108b and 108d illuminated or “selected.” The terms “properly fabricated” or “good” as used herein refer to the ability of a particular interconnect 112 to conduct a sufficient amount of electrical current between at least two reception nodes of electrical circuit 100.

Row 2 of FIG. 2 illustrates the illumination pattern of LEDs 108 that would occur if electrical interconnect 112a tested as faulty or open while electrical interconnect 112b functioned properly. The terms “faulty” or “open” as used herein refer to the inability of a particular interconnect 112 to conduct a sufficient amount of electrical current between at least two reception nodes of electrical circuit 100. Under such circumstances, LED 108a would be illuminated, indicating a “no-go” status, and LED 108c would not be illuminated, indicating a “go” status. Row 4 of FIG. 2 illustrates the opposite conditions of Row 2, meaning Row 4 indicates the states of LEDs 108 resulting from electrical interconnect 112a functioning properly and electrical interconnect 112b testing as open. As shown in Row 3 of FIG. 2, if electrical interconnects 112a and 112b are both open then LED 108a and LED 108c would each be illuminated, indicating a “no-go” status for both electrical interconnects 112a and 112b in this example.

As illustrated in Row 5 of FIG. 2, the greatest current is present in this example when both tested portions of conductive interconnects 112a and 112b are electrically shorted, thus shunting current from LEDs 108a, 108b, and 108c, though LED 108d may still be illuminated. The current may thus be represented as 36 volts minus 2 volts, resulting in a current of 34 volts divided by 1,400 ohms, or 24.2 milliamps-still within the limits of a selected LED 108 in this example. Thus, this example not only provides a mechanism for testing the continuity of multiple electrical interconnects 112, but also may be used to determine if at least two of the interconnects 112 are shorted together.

Various embodiments may provide the above functionality without necessarily requiring electronic regulation of circuit 100. For example, some LEDs 108 may be capable of producing a usable indication output over a wide range of currents up to an absolute maximum rating, thereby possibly enhancing the economical efficiency of various embodiments using current-limiting resistor(s).

In some alternative embodiments, however, current regulation may be desired for controlled light output from LEDs 108. For example, in some alternative embodiments, constant light output from LEDs 108 may be effected by placing a commercial current limiting device in series with the load (e.g., in place of resistor 104). One such device is the CL2 Constant Current LED Driver IC (CL2) manufactured by Supertex Incorporated. The CL2 device, or some other equivalent device, may be used to limit the current of circuit 100 to approximately 20 milliamps, irrespective of the number of LEDs 108 in series. This steady current permits LED 108 operation at constant brightness and at a level not exceeding their maximum forward current. The CL2 device is advertised as working with up to 90 volts applied. With a minimum device voltage drop of about 5 volts, the CL2 device could supply, assuming a 2 volt forward voltage drop per LED 108, 90 volts minus 5 volts, which equals 85 volts; 85 volts divided by 2 volts equals 42.5 volts, or a total of forty-two LEDs 108 in series, at least in theory. In a practical circuit, forward voltage for each LED 108 may vary slightly and thus forty LEDs 108 may be a more practical maximum number for embodiments using a current limiting device such as CL2. With three LEDs 108 employed per pair of conductive interconnects 112 tested, thirteen conductive interconnects 112 may be tested in one such alternative circuit. Greater or lesser numbers of conductive interconnects may be possible depending upon variable factors such as forward voltage drop, variations in temperature, LED driver circuit variations, etc.

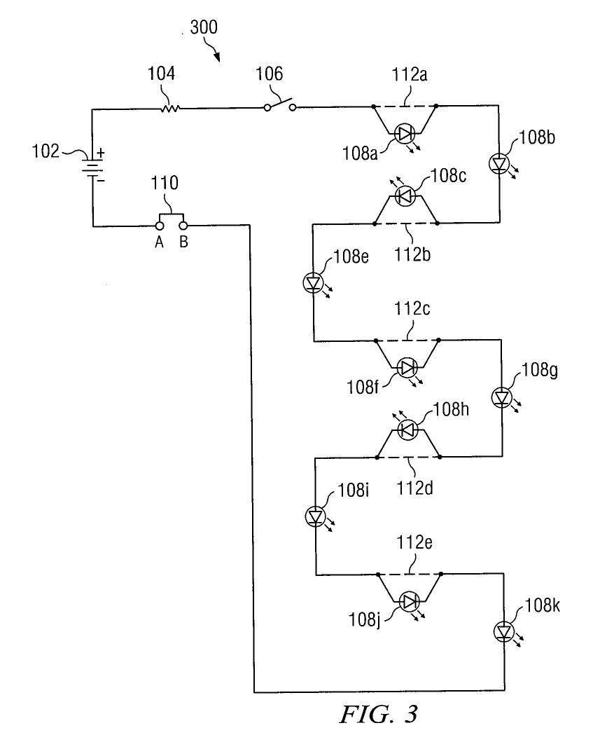

FIG. 3 is a schematic for a circuit 300 that may be used to expand the testing capability of the circuit 100 of FIG. 1A. In this example, the components of circuit 300 are substantially similar in structure and function to respective components of circuit 100 of FIG. 1A, with the exception that circuit 300 includes additional indicators 108e, 108f, 108g, 108h, 108i, 108j and 108k (coupled in series with respect to each other) and reception nodes configured to receive additional interconnects 112c, 112d, and 112e for testing. Indicator 108k in particular is substantially similar in structure and function to indicator 108d in FIGS. 1A and 1B. For example, indicator 108k may be capable of indicating whether power is indeed applied to circuit 300. In addition, indicator 108k may be capable of indicating whether all interconnects 112 under test have continuity but are shorted one to another (e.g., in the case where each indicator 108 includes a respective LED and LED 108k is the only one illuminated).

In this example, indicators 108e, 108g, 108i, and 108k are green LEDs and indicators 108f, 108h, and 108j are red LEDs, thereby enabling “go” and “no-go” status indications in a manner substantially similar to that described above. Thus, the circuit 100 of FIG. 1A can be readily expanded in any of a variety of ways to enable the efficient testing of any suitable number of interconnects 112.

Various embodiments may include any of a variety of aural or visual indicators 108 (e.g., piezoelectric speakers and/or visual LEDs), which in some cases may each have a wide range of operating current and/or an internal regulator. In this manner, some embodiments may regulate current to a large numbers of indicators 108 without necessarily using a separate current limiting device.

Should voltage potentials in a continuity testing device 150 be deemed too high for possible human contact, the device may be constructed using physical and/or electrical interlocks, such as a non-conducting protective box or shield over the conductive interconnects 112, which activates the continuity testing device 150 upon being closed over the device. Alternatively, multiple reproductions of circuit 100 could be repeatedly used to test a sample having a large number of conductive interconnects 112, the voltage potential being selected to operate with a given number of interconnects in each portion.

In various embodiments, it may be desired to test the integrity of one or more conductive interconnects 112 at a given operating current. In some such embodiments, circuit 100 may enable such a test by shunting each LED 108 with a respective shunt resistor. The shunt resistors may be selected by Ohm's law to permit a voltage drop of about two volts when operating in parallel with a respective LED 108. The resistance, and hence the shunt current, may be calculated to provide a selected operating current for the continuity testing device. An electronic constant current source designed for the desired testing current may be used in place of the CL2 circuit described previously. Such constant current circuits may replace voltage source 102 of circuits 100 and/or 300, for example, with a larger battery, batteries, or an AC-powered supply of higher current capability. Thus, the continuity testing device 150 may be designed to reveal any of a variety of additional problems, such as errors in wiring or failures in a crimping technique. More specifically, one example of such an error may be the crimping or soldering termination of but a few strands of a wire consisting of multiple strands. Such a wire may establish electrical continuity, but may be incapable of carrying larger currents for which it may be intended. Various test sets may be configured to indicate the inability of the wire to carry the intended current.

The particular test set described with reference to FIGS. 1A through 3 does not necessarily use clocking, sequencing, or computational test circuitry, so a simultaneous real-time test of every installed electrical interconnect 112 is constantly provided. Thus, the identifying of a pervasive problem in conductive interconnects 112 and the location of intermittent connections are greatly enhanced because physical tapping, twisting, shaking, or other manipulation of the installed conductive interconnects 112 reveals a momentarily open or short circuit instantly to the operator, where such detection may have been otherwise masked by a sequenced testing circuit, that is, testing of a connection other than the failed connection at the instant the failure occurs.

In some applications, ensuring properly functioning interconnects free of shorts, solder blobs, open circuits, etc., is a prime consideration. Conventional testing, however, commonly involves complex testing apparatuses, tooling, maintenance, and expended resources in design, which may collectively result in significant cost increases. Consequently, some conventional applications undergo little to no testing, but instead rely on expensive, high-capability processes that still experience rare incidences of what may be catastrophic failure. In addition, some conventional testing methods are time consuming and provide inadequate information. For example, some conventional testing methods test for continuity one conductor at a time and thus may not discover short circuits between conductors and may be prone to error from misidentifying a particular wire or connector pin. Other conventional methods involve connecting each wire of a cable in series with its neighboring wire, thus requiring continuity in all wires for success. Such methods provide little to no indication of the particular wire or wires with the problem should one be detected. Moreover, if jumpers are used to interconnect wires of a cable for such a serial connection, the jumpers themselves could be defective. Indeed, the test equipment may itself be defective and provide a false alarm or fail to detect a particular problem.

Accordingly, certain embodiments of the present disclosure provide a continuity testing device 150 having a design that may be efficiently manufactured using inexpensive electronic components, including: LEDs, connectors, resistors, and a battery. The time required for testing multiple conductive interconnects in some embodiments is reduced to a single installation event. Some of the example embodiments inherently test the continuity testing device itself (e.g., one or more indicators may illuminate when power is applied and no cable under test is installed, thereby indicating the continuity testing device 150 is functioning properly). The testing may be efficiently executed, in some embodiments, by simply inserting a test cable into mating connectors of the continuity testing device, without any further switching. Various embodiments may provide discrete indications (e.g., in the form of illuminated LEDs 108 and/or audible sounds) that specifically identify which particular interconnect(s) have a problem when multiple interconnects are simultaneously tested. Various embodiments may be highly economical, easily reproducible, and even expendable.

Although the present disclosure has been described with several embodiments, a myriad of changes, variations, alterations, transformations, and modifications may be suggested to one skilled in the art, and it is intended that the present disclosure encompass such changes, variations, alterations, transformations, and modifications as fall within the scope of the appended claims.

What is claimed is:

1. A method for testing electronics, the method comprising:
forming at least a portion of an electrical circuit by electrically coupling a plurality of indicators in series with respect to each other such that each indicator is operable to substantially simultaneously indicate an electrical characteristic of a respective one or more of a plurality of conductive interconnects;
coupling respective ones of the plurality of conductive interconnects a respective pair of a plurality of reception nodes of the electrical circuit such that each conductive interconnect is coupled to the electrical circuit in parallel with a respective one of a plurality of indicators; and
determining, based at least in part on the electrical characteristics indicated by at least three of the plurality of indicators, whether two of the plurality of conductive interconnects are electrically shorted together.

2. The method of claim 1, further comprising determining, based at least in part on the electrical characteristic indicated by at least one of the plurality of indicators, whether one of the plurality of conductive interconnects is capable of electrically coupling together two of the plurality of reception nodes.

3. The method of claim 1, further comprising determining, based at least in part on the electrical characteristic indicated by at least one of the plurality of indicators, whether one of the plurality of conductive interconnects is capable of conducting a predetermined threshold level of current between two of the plurality of the plurality of reception nodes.

4. The method of claim 1, further comprising determining, based at least in part on the electrical characteristic indicated by at least one of the plurality of indicators, whether one of the plurality of conductive interconnects comprises an intermittent electrical connection.

5. The method of claim 1, further comprising maintaining a predetermined electrical current for each indicator of the plurality of indicators.

6. The method of claim 1, wherein each indicator comprises a respective light emitting diode (LED) operable to indicate the electrical characteristic of the respective one or more of the plurality of conductive interconnects by outputting one of a plurality of illumination states comprising one or more on states and an off state.

7. The method of claim 1, further comprising determining, based at least in part on an electrical characteristic indicated by a tester indicator coupled in series with respect to the plurality of reception nodes, an operational status of the electrical circuit that is independent of the plurality of conductive interconnects.

8. A portable electronics testing device comprising:
an electrical circuit comprising:
a plurality of indicators coupled in series with respect to each other and each operable to substantially simultaneously indicate an electrical characteristic of a respective one or more of a plurality of conductive interconnects, the electrical characteristics indicated by at least three of the plurality of indicators further operable to indicate whether at least two of the plurality of conductive interconnects are electrically shorted together; and
a plurality of reception nodes electrically coupled in series with respect to each other and each operable to electrically couple to respective nodes of the plurality of conductive interconnects such that each conductive interconnect is coupled to the electrical circuit in parallel with a respective one of the plurality of indicators.

9. The portable electronics testing device of claim 8, wherein the respective one of the plurality of indicators for each conductive interconnect is further operable to indicate whether the conductive interconnect is capable of electrically coupling together two of the plurality of reception nodes.

10. The portable electronics testing device of claim 8, wherein the respective one of the plurality of indicators for each conductive interconnect is further operable to indicate whether the conductive interconnect is capable of conducting a predetermined threshold level of current.

11. The portable electronics testing device of claim 8, wherein each indicator comprises a respective light emitting diode (LED) operable to indicate the electrical characteristic of the respective one or more of the plurality of conductive interconnects by outputting one of a plurality of illumination states comprising one or more on states and an off state.

12. The portable electronics testing device of claim 8, wherein the electrical circuit further comprises a tester indicator coupled in series with respect to the plurality of reception nodes, the tester indicator operable to indicate an operational status of the electrical circuit that is independent of the plurality of conductive interconnects.

13. The portable electronics testing device of claim 8, further comprising a current limiting device coupled in series with respect to the plurality of reception nodes, the current limiting device operable to maintain a predetermined electrical current for each indicator of the plurality of indicators

14. The portable electronics testing device of claim 8, wherein at least one indicator comprises a respective speaker operable to indicate the electrical characteristic of the respective one or more of the plurality of conductive interconnects by outputting sound.

15. The portable electronics testing device of claim 8, wherein the portable electronics testing device is a handheld device.

16. The portable electronics testing device of claim 8, wherein the plurality of conductive interconnects collectively form at least a portion of a ribbon cable.

17. A method for testing electronics, the method comprising:
forming at least a portion of an electrical circuit by electrically coupling a plurality of indicators in series with respect to each other such that each indicator is operable to substantially simultaneously indicate an electrical characteristic of a respective one or more of a plurality of conductive interconnects;
coupling respective ones of the plurality of conductive interconnects a respective pair of a plurality of reception nodes of the electrical circuit such that each conductive interconnect is coupled to the electrical circuit in parallel with a respective one of a plurality of indicators;
determining, based at least in part on the electrical characteristics indicated by at least three of the plurality of indicators, whether two of the plurality of conductive interconnects are electrically shorted together;
determining, based at least in part on the electrical characteristic indicated by at least one of the plurality of indicators, whether one of the plurality of conductive interconnects is capable of electrically coupling together two of the plurality of reception nodes; and
determining, based at least in part on the electrical characteristic indicated by at least one of the plurality of indicators, whether one of the plurality of conductive interconnects is capable of conducting a predetermined threshold level of current between two of the plurality of the plurality of reception nodes.

18. The method of claim 17, further comprising maintaining a predetermined electrical current for each indicator of the plurality of indicators.

19. The method of claim 17, wherein each indicator comprises a respective light emitting diode (LED) operable to indicate the electrical characteristic of the respective one or more of the plurality of conductive interconnects by outputting one of a plurality of illumination states comprising one or more on states and an off state.

20. The method of claim 17, further comprising determining, based at least in part on an electrical characteristic indicated by a tester indicator coupled in series with respect to the plurality of reception nodes, an operational status of the electrical circuit that is independent of the plurality of conductive interconnects.
